(19) United States
(12) Patent Application Publication
(10) Pub. No.: US 2005/0161806 A1
(43) Pub. Date: Jul. 28, 2005

(54) Area array packages with overmolded pin-fin heat sinks

(76) Inventors: Mysore P. Divakar, San Jose, CA (US); Thomas H. Templeton JR., Fremont, CA (US)

Correspondence Address: QUARLES & BRADY LLP, RENAISSANCE ONE, TWO NORTH CENTRAL AVENUE, PHOENIX, AZ, 85004-2391, US

(21) Appl. No.: 10/763,795

(22) Filed: Jan. 22, 2004

(51) Int. Cl. H01L 23/34

(52) U.S. Cl. 257/717

(57) ABSTRACT

A semiconductor device has a semiconductor die (12) mounted to a leadframe (25). The semiconductor die is a power semiconductor device. A thermally conductive overmolding compound (22) is formed over the semiconductor die. The overmolding compound is made with a thermally conductive epoxy that conducts heat in the range of 2-5 watts/meter K. A pin-fin heat sink (24) is mounted to a top surface of the thermally conductive overmolding compound. The heat sink has a solid base (28) with a plurality of pin-fins (30) extending from the base. Scour lines (40) are cut in the base between the pin-fins. The heat generated by the semiconductor die is dissipated through the thermally conductive overmolding compound to the pin-fin heat sink.

### FIELD OF THE INVENTION

The present invention relates in general to semiconductor devices and, more particularly, to an area array package with pin-fin heat sinks concurrently disposed on the overmolding compound.

### BACKGROUND OF THE INVENTION

Semiconductor devices are commonly used in the construction of electronic circuits for many types of electronic products. The manufacturing of a semiconductor device typically involves growing a cylindrical-shaped silicon (or other base semiconductive material) ingot. The ingot is sliced into circular flat wafers. Through a number of thermal, chemical, and physical manufacturing processes, active semiconductor devices and passive devices are formed on one or both surfaces of the wafer. The wafer is cut into individual rectangular semiconductor dies which are then mounted and attached to a leadframe, encapsulated with an overmolding compound, and packaged as discrete or integrated circuits. The packaged discrete and integrated circuits are mounted to a printed circuit board and interconnected to perform the desired electrical function.

One type of semiconductor device is known as a power metal oxide semiconductor field effect transistor (power MOSFET). Power MOSFETs are commonly used in power supplies, power converters, energy systems, computer systems, telecommunications, motor control, automotive, and consumer electronics. Semiconductor devices containing power MOSFETs, and other semiconductor die containing a large number of transistors, or operating at high clocking speeds, are known to consume large amounts of power and generate significant heat. The heat must be dissipated from the heat-generating semiconductor device in order to cool the device and maintain an acceptable operating environment. The generated heat can also adversely effect the operation of neighboring semiconductor devices.

The dissipation of heat generated by power-consuming semiconductor devices can take a number of approaches and forms. If the heat generation issue is low to moderate, sometimes just the use of a fan to force air across the printed circuit board is sufficient to dissipate the heat and maintain the operating temperature within the desired range. In other heat dissipation solutions, a heat sink is attached to the heat-generating semiconductor device to provide an avenue or mechanism to draw the heat out of the device. Some heat sinks are attached to the bottom of the heat-generating semiconductor device, between the device and the printed circuit board. However, dissipating all heat into the printed circuit board is usually undesirable for the board design.

Other heat sinks are mounted to the top of the heat-generating semiconductor devices, i.e., on the overmolding compound or other housing or environmental encapsulation protecting the semiconductor die. The heat generated by the semiconductor die is channeled to the heat sink by way of a thermally conductive heat slug or shim mounted to the leadframe supporting the semiconductor die. The circulating fan forces air across the heat sink to dissipate the heat into the surrounding air and usually out the cabinet housing the printed circuit board. Such top-mounted heat sinks often include fins to increase the surface area of the heat sink and increase the heat dissipation effectiveness and efficiency.

The top-mounted heat sinks are typically glued or attached with an adhesive to the hardened overmolding compound. Most if not all prior art overmolding compounds are thermal insulators and poor heat transfer conduits between the heat-generating semiconductor die and heat sink. To transfer the heat from the semiconductor die to the heat sink, a thermally conductive heat slug or shim is mounted to the leadframe supporting the semiconductor die. The heat slug is a rectangular piece of metal in thermal contact with both the heat generating semiconductor die and the heat sink. The heat slug or shim is routed through or around the overmolding compound to the heat sink. The heat is then transferred from the semiconductor die through the heat slug to the heat sink in order to dissipate the heat from the semiconductor package.

The heat slug adds cost and volume to the IC package. Moreover, the heat slug may have a small cross sectional area compared to the surface area of the semiconductor package. The small cross sectional area of the heat slug limits its heat transfer performance.

A need exists to dissipate heat from a semiconductor die without the need for a heat slug connecting the semiconductor die to the heat sink.

### SUMMARY OF THE INVENTION

In one embodiment, the present invention is a semiconductor device comprising a semiconductor die. A thermally conductive overmolding compound is disposed on the semiconductor die. A pin-fin heat sink is mounted to a surface of the thermally conductive overmolding compound. The heat generated by the semiconductor die is dissipated through the thermally conductive overmolding compound to the pin-fin heat sink.

In another embodiment, the present invention is a method of manufacturing a semiconductor device comprising providing a semiconductor die, forming a thermally conductive overmolding compound over the semiconductor die, and mounting a heat sink on a surface of the thermally conductive overmolding compound.

In yet another embodiment, the present invention is a method of manufacturing a semiconductor device comprising providing a plurality of semiconductor die, providing a leadframe assembly, mounting the plurality of semiconductor die to the leadframe assembly, forming a thermally conductive overmolding compound over the leadframe assembly, and mounting a panel of heat sinks on a surface of the thermally conductive overmolding compound. Each heat sink in the panel of heat sinks is disposed over one of the plurality of semiconductor die.

### BRIEF DESCRIPTION OF THE DRAWINGS

FIG. 1 is a cross-sectional view of a power semiconductor package;

FIG. 2 illustrates the power semiconductor package with a pin-fin heat sink;

FIG. 3 illustrates a panel of heat sinks disposed over an overmolding compound which has been deposited on an array of semiconductor die mounted to a leadframe assembly;

FIG. 4 is a top-view of the pin-fin heat sink;

FIG. 5 is a top-view of an alternative pin-fin heat sink;

FIG. 6 is a perspective view of the pin-fin heat sink mounted to the semiconductor package;

FIG. 7 is a perspective view of the alternative pin-fin heat sink mounted to the semiconductor package;

FIG. 8 is a top-view of the pin-fin heat sink with scour lines;

FIG. 9 illustrates the power semiconductor package in a ball grid array configuration;

FIG. 10 illustrates the power semiconductor package in a land grid array configuration; and

FIG. 11 illustrates the power semiconductor package with a heat slug disposed in the thermally conductive overmolding compound.

### DETAILED DESCRIPTION OF THE DRAWINGS

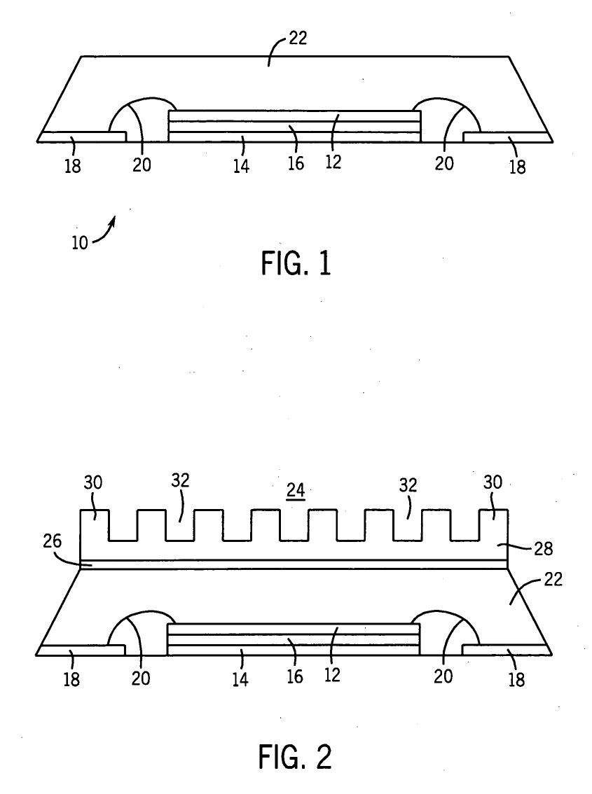

Referring to FIG. 1, a cross-sectional view of semiconductor package 10 is shown. Semiconductor 10 is formed as an area array package, e.g., quad flatpack no lead package (QFN), land grid array (LGA), ball grid array (BGA), and other form of chip scale package. The semiconductor package is typically 15 by 15 millimeters (mm) square or larger. Semiconductor package 10 houses semiconductor die or device 12.

A semiconductor wafer is formed using known semiconductor manufacturing processes. The wafer is cut into individual rectangular semiconductor die 12. Each semiconductor die 12 is mounted to paddle 14 in a leadframe assembly with an adhesive 16 or other die attach material. Semiconductor die 12 is wire-bonded to pads 18 on the leadframe with wire bonds 20. Wire bonds 20 are made with gold.

Overmolding compound 22 is deposited over the leadframe assembly and the plurality of semiconductor die 12. Overmolding compound 22 is a thermally conductive epoxy with a filler comprising small granules of aluminum oxide or crystalline silica about 10 microns in diameter. Overmolding compound 22 is thermally conductive in the range of 2-5 watts/meter K. Thermally conductive epoxy is available under the tradename of IMP-2 made by Sumitomo, KMC-620 made by Shin Etsu, and High K Mold Compounds made by Hitachi.

After being deposited over semiconductor die 12, overmolding compound 22 undergoes a curing process to create a hardened protective shell. During the curing process, while overmolding compound 22 is still in a tacky state, i.e., before it has cured to its final % hardened state, pin-fin heat sink 24 is mounted on overmolding compound 22 as shown in FIG. 2. Preferably, heat sink 24 is attached to overmolding compound 22 during the first half of the curing process. The surface of overmolding compound 22 may be pre-treated with thermal adhesive 26 to improve the adhesion of pin-fin heat sink 24 to overmolding compound 22. Adhesive 26 is thermally conductive in the range of 3-20 watts/meter K. Thermal adhesive 26 may also contain a conductive silver filler.

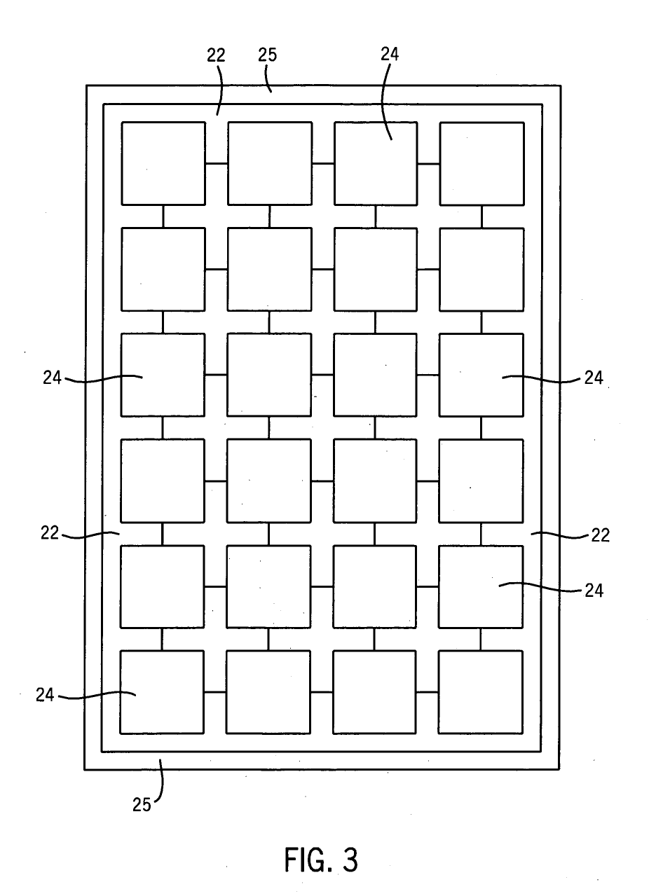

In FIG. 3, leadframe assembly 25 shown as an interconnected array of semiconductor package support platforms. In one embodiment, leadframe assembly 25 forms 36 packages (6 by 6). In another embodiment, the leadframe assembly forms 80 packages (8 by 10). Each support platform in leadframe assembly 25 includes a paddle to mount semiconductor die 12, pads to connect wire bonds, and pins for making electrical connection to the printed circuit board. A number of semiconductor dies 12 are mounted to the array of paddles in the leadframe assembly. That is, one semiconductor die 12 is attached to each die paddle 14 on the leadframe assembly with adhesive 16 or other die attach material. The overmolding compound 22 is then deposited on the entire leadframe assembly to environmentally seal semiconductor die 12.

Each pin-fin heat sink 24 is provided as part of a panel of interconnected heat sinks. The panel of heat sinks 24 is spaced such that each heat sink is oriented directly over one semiconductor die 12. The panel of heat sinks 24 is mounted to overmolding compound 22 before it has cured as described above. The overmolding compound 22 is allowed to finish the curing process to a hardened state. By that time, the panel of heat sinks 24 is firmly attached to the hardened overmolding compound 22.

The leadframe assembly 25 is singulated to separate the individual semiconductor packages 10. The singulation process involves cutting leadframe assembly 25 and overmolding compound 22 with shear, saw, or other cutting device. Since the panel of heat sinks 24 is mounted to the overmolding compound 22, the singulation process also cuts the panel of heat sinks. The semiconductor 10 with attached heat sinks 24 are thus separated into individual packages.

Semiconductor 10 is useful in the construction of electronic circuits for many types of electronic products. Semiconductor 10 is particular applicable to power semiconductor devices, i.e., devices that can switch about 0.5 to 1.0 amperes or more conduction current with an applied operating voltage between very low voltage (e.g., 5 volts) to tens and even hundreds of volts.

One type of power semiconductor device is known as a power metal oxide semiconductor field effect transistor (power MOSFET). Power MOSFETs are commonly used in switching power supplies, power conversion, power management, energy systems, computer systems, telecommunications, motor control, automotive, and consumer electronics. Semiconductor devices containing power MOSFETs, and other semiconductor die containing a large number of transistors or operating at high clocking speeds, are known to consume a large amount of power and generate a significant amount of heat. The heat must be dissipated from the heat-generating semiconductor device in order to cool the device and maintain an acceptable operating environment. Pin-fin heat sink 24 is useful in dissipating the heat generated by semiconductor die 12.

Heat sink 24 is made with aluminum or copper with black anodized finish. Other surface finishes include nickel, solder plated, chemical etch, and chemical film. Heat sink 24 comprises a solid base 28 with a plurality of pin-fins 30 extending from base 28. Heat sink 24 begins with a solid block of aluminum or copper. Pin-fins 30 are formed by cutting channels or streets 32 in the solid block. Channels 32 are cut in length-wise and cross-wise direction, i.e., X and Y directions, to form the plurality of pin-fins 30.

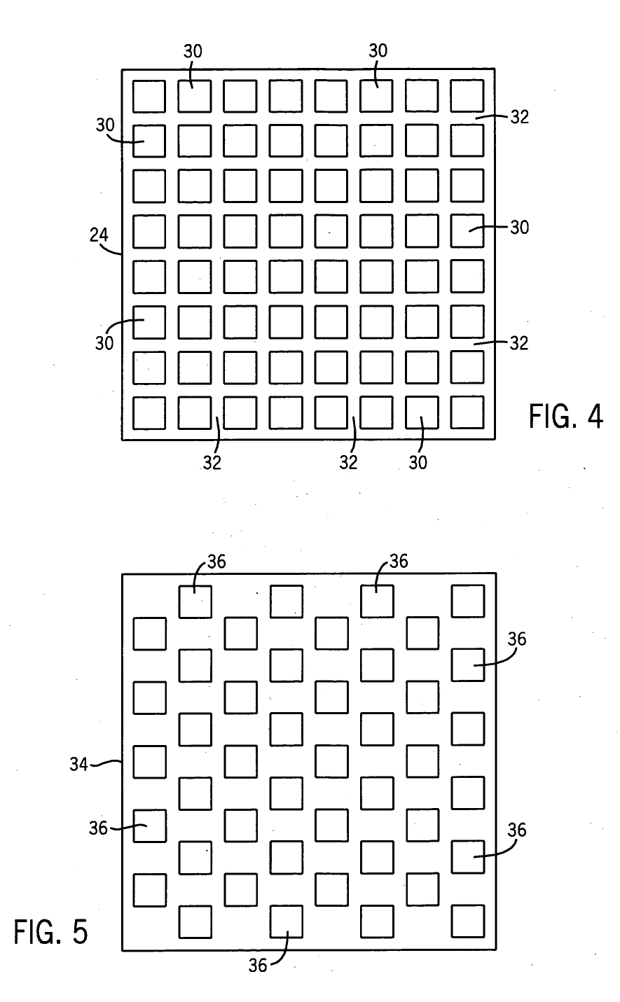

A top view of pin-fin heat sink 24 is shown in FIG. 4. Channels 32 run length-wise and cross-wise to form pin-fins 30. Each pin-fin 30 is about 1-2 mm in width by 1-2 mm in length and about 4-15 mm in height. The width of channel 32 is about 1-5 mm.

A top-view of another pin-fin heat sink 34 is shown in FIG. 5. Pin-fins 36 are offset or staggered in alternating rows and columns. Each pin-fin 36 is about 1-2 mm in width by 1-2 mm in length and about 4-15 mm in height. The distance between adjacent columns of pin-fins is about 1-3 mm. The staggered design helps avoid impeding or choking of the airflow.

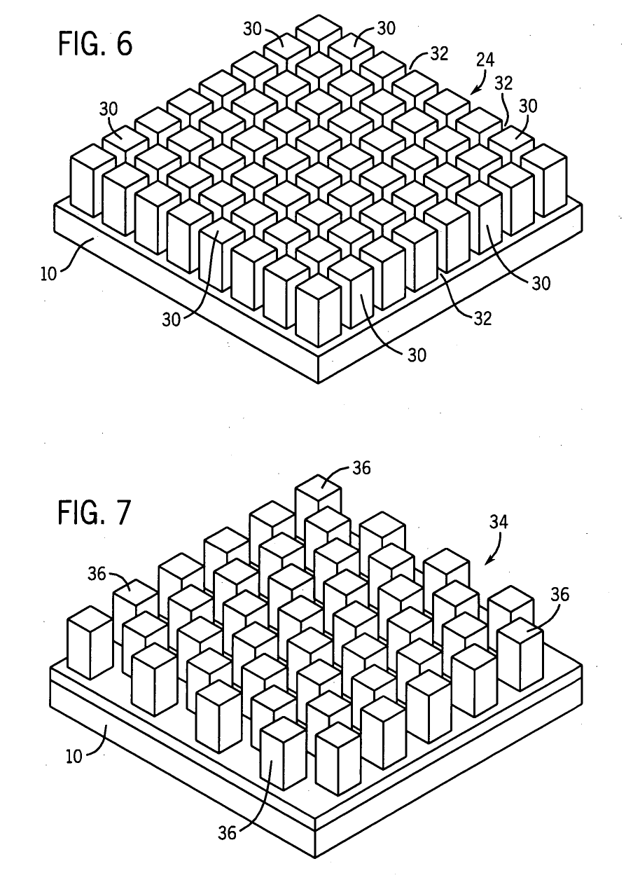

A perspective view of pin-fin heat sink 24 mounted to semiconductor package 10 is shown in FIG. 6. Again, channels 32 run length-wise and cross-wise between pin-fins 30. A perspective view of pin-fin heat sink 34 is shown in FIG. 7. Pin-fins 36 are shown offset in alternating or staggered rows and columns. The rigid structure of heat sinks 24 and 34 reduce warpage in semiconductor package 10.

Semiconductor die 12 generates heat during its normal operation. The heat must be dissipated away for semiconductor die 12. The heat is conducted or transferred from semiconductor die 12 through thermally conductive overmolding compound 22 to heat sink 24. The thermally conductive overmolding compound 22 covers substantially the surface area of the package and maximizes the cross sectional area for the thermal conduction path. Accordingly, the use of high thermal conductivity molding compound 22 provides low thermal gradients from semiconductor die 12 to heat sink 24. The heat is distributed among pin-fins 30 of heat sink 24. A fan forces air across pin-fins 30 remove the heat from heat sink 24 and semiconductor package 10. The heat is dissipated in the atmosphere above and away from semiconductor package 10 and any printed circuit board to which semiconductor package 10 is mounted.

Transferring heat through the thermally conductive overmolding compound 22 is more efficient in terms of its heat transfer conduit cross-sectional area as compared to the heat slugs and shims found in the prior art. Furthermore, by using a thermally conductive overmolding compound as the heat transfer conduit, the heat slugs and shims are no longer required which saves space and manufacturing costs.

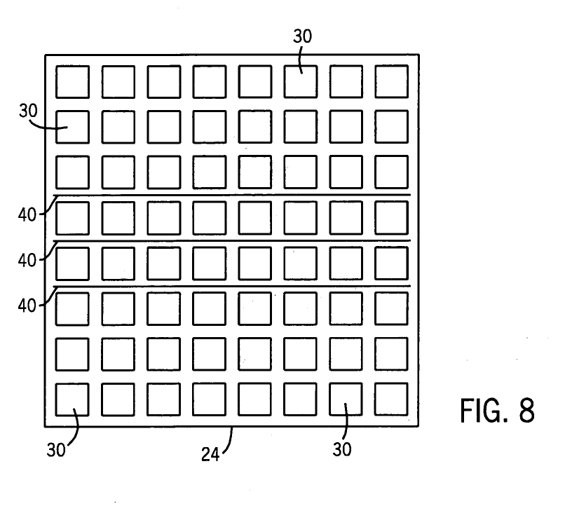

Turning to FIG. 8, the top view of heat sink 24 is shown with scour lines 40 disposed between rows of pin-fins 30. Scour lines 40 are cut into base 28 during the singulation of semiconductor package 10 as described above. The same saw blade that singulates semiconductor package 10 also cuts scour lines 40. Scour lines 40 provides enhanced moisture resistance of semiconductor package 10 and allow the overmolding compound to breathe.

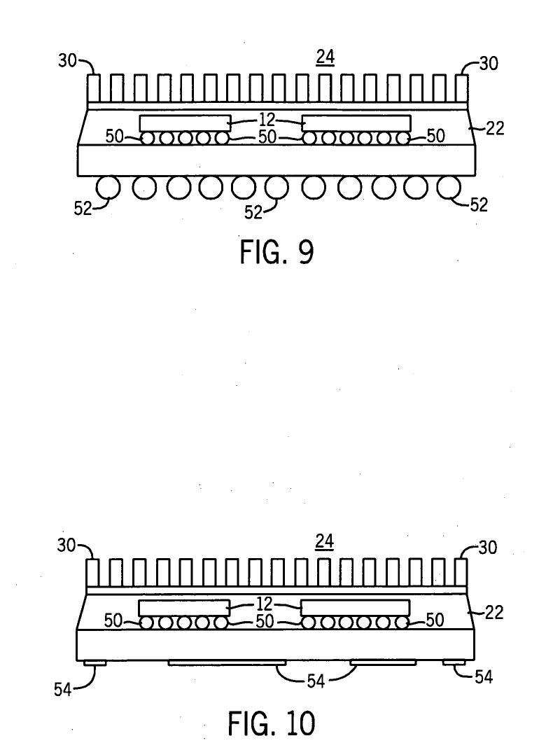

The power semiconductor package 10 can be arranged in a variety of package configurations and styles. As an example, FIG. 9 illustrates power semiconductor package 10 in a ball grid array configuration. Ball grids 50 and 52 provide connectivity between semiconductor die 12 and external circuits. FIG. 10 illustrates power semiconductor package 10 in a land grid array configuration. Ball grids 50 and land grids 54 provide connectivity between semiconductor die 12 and external circuits. Components with a similar function are assigned the same reference numbers used in the previous figures.

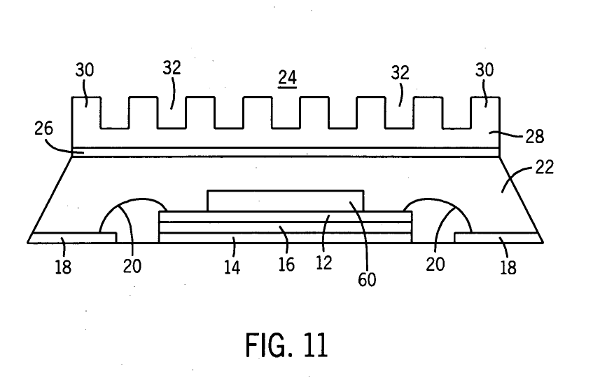

In FIG. 11, an alternate embodiment of the power semiconductor package is shown with heat slug 60 disposed above semiconductor die 12. Components with a similar function are assigned the same reference numbers used in FIG. 2. Heat slug 60 is used in combination with thermally conductive overmolding compound 22 as the heat transfer mechanism between semiconductor die 12 and pin-fin heat sink 24. Heat slug 60 does not extend the complete distance between semiconductor die 12 and pin-fin heat sink 24. Heat slug 60 radiates the heat into overmolding compound 22, which in turn conducts the heat to pin-fin heat sink 24. The heat transfer between semiconductor die 12 and pin-fin heat sink 24 is thus accomplished in part by heat slug 60 and in part by thermally conductive overmolding compound 22.

A person skilled in the art will recognize that changes can be made in form and detail, and equivalents may be substituted for elements of the invention without departing from the scope and spirit of the invention. The present description is therefore considered in all respects to be illustrative and not restrictive, the scope of the invention being determined by the following claims and their equivalents as supported by the above disclosure and drawings.

1. A semiconductor device, comprising:
a semiconductor die;
a thermally conductive overmolding compound disposed on the semiconductor die; and
a pin-fin heat sink mounted to a surface of the thermally conductive overmolding compound, wherein heat generated by the semiconductor die is dissipated through the thermally conductive overmolding compound to the pin-fin heat sink.

2. The semiconductor device of claim 1, wherein the semiconductor die is a power semiconductor device.

3. The semiconductor device of claim 1, wherein the overmolding compound is made with a thermally conductive epoxy.

4. The semiconductor device of claim 1, wherein the overmolding compound thermally conducts in the range of 2-5 watts/meter K.

5. The semiconductor device of claim 1 further including a leadframe supporting the semiconductor die.

6. The semiconductor device of claim 5 further including a plurality of wire bonds coupled between the semiconductor die and the leadframe.

7. The semiconductor device of claim 1, wherein the pin-fin heat sink includes a base with a plurality of pin-fins extending from the base.

8. The semiconductor device of claim 7, wherein the base includes scour lines between the pin-fins.

9. The semiconductor device of claim 1 housed in a quad flatpack no lead package, land grid array package, or ball grid array package.

10. The semiconductor device of claim 1 further including a heat slug disposed above the semiconductor die without contacting the pin-fin heat sink.

11. A semiconductor device, comprising:
a semiconductor die;
a thermally conductive overmolding compound disposed on the semiconductor die; and
a heat sink disposed on a surface of the thermally conductive overmolding compound.

12. The semiconductor device of claim 11, wherein heat generated by the semiconductor die is dissipated through the thermally conductive overmolding compound to the heat sink.

13. The semiconductor device of claim 11, wherein the semiconductor die is a power semiconductor device.

14. The semiconductor device of claim 11, wherein the overmolding compound is made with a thermally conductive epoxy.

15. The semiconductor device of claim 11, wherein the overmolding compound thermally conducts in the range of 2-5 watts/meter K.

16. The semiconductor device of claim 11, wherein the heat sink includes a base with a plurality of pin-fins extending from the base.

17. The semiconductor device of claim 16, wherein the base includes scour lines between the pin-fins.

18. The semiconductor device of claim 11 housed in a quad flatpack no lead package, land grid array package, or ball grid array package.

19. The semiconductor device of claim 11 further including a heat slug disposed above the semiconductor die without contacting the heat sink.

20. A method of manufacturing a semiconductor device, comprising:
providing a semiconductor die;
forming a thermally conductive overmolding compound over the semiconductor die; and
mounting a heat sink on a surface of the thermally conductive overmolding compound.

21. The method of claim 20, wherein heat generated by the semiconductor die is dissipated through the thermally conductive overmolding compound to the heat sink.

22. The method of claim 20, wherein the semiconductor die is a power semiconductor device.

23. The method of claim 20, wherein the overmolding compound is made with a thermally conductive epoxy.

24. The method of claim 20, wherein the heat sink is mounted on the thermally conductive overmolding compound before final cure of the thermally conductive overmolding compound.

25. The method of claim 20, wherein the heat sink includes a base with a plurality of pin-fins extending from the base.

26. The method of claim 25, wherein the base includes scour lines between the pin-fins.

27. The method of claim 20 further including the step of housing the semiconductor device in a quad flatpack no lead package, land grid array package, or ball grid array package.

28. The method of claim 20 further including the step of disposing a heat slug above the semiconductor die without contacting the pin-fin heat sink.

29. A method of manufacturing a semiconductor device, comprising:
providing a plurality of semiconductor die;
providing a leadframe assembly;
mounting the plurality of semiconductor die to the leadframe assembly;
forming a thermally conductive overmolding compound over the leadframe assembly; and
mounting a panel of heat sinks on a surface of the thermally conductive overmolding compound, wherein each heat sink in the panel of heat sinks is disposed over one of the plurality of semiconductor die.

30. The method of claim 29, wherein heat generated by the semiconductor die is dissipated through the thermally conductive overmolding compound to the heat sink.

31. The method of claim 29, wherein the overmolding compound is made with a thermally conductive epoxy.

32. The method of claim 29, wherein the panel of heat sinks is mounted on the thermally conductive overmolding compound before final cure of the thermally conductive overmolding compound.

33. The method of claim 29 further including the step of singulating the leadframe assembly such that the singulation cuts through the thermally conductive overmolding compound and the panel of heat sinks.

34. The method of claim 33 further including the step of forming scour lines in a base of each heat sink of the panel of heat sinks.
